(19) United States
(12) Patent Application Publication
(10) Pub. No.: US 2021/0396878 A1
(43) Pub. Date: Dec. 23, 2021

(54) OPTICAL RANGING DEVICE

(71) Applicant: DENSO CORPORATION, Kariya-city (JP)

(72) Inventor: Yoshihide TACHINO, Kariya-city (JP)

(21) Appl. No.: 17/466,647

(22) Filed: Sep. 3, 2021

Related U.S. Application Data
(63) Continuation of application No. PCT/JP2020/002256, filed on Jan. 23, 2020.

(30) Foreign Application Priority Data
Mar. 6, 2019 (JP) 2019-040535

(51) Int. Cl. G01S 17/26; G01S 7/4915; G01S 7/481

(52) U.S. Cl. CPC G01S 17/26; H01L 31/107; G01S 7/4817; G01S 7/4915

(57) ABSTRACT

An optical ranging device includes: a photodetector configured to output an output signal corresponding to an amount of a received light; a scanning scanner configured to switch between a state where outside light is permitted to enter the photodetector and a dark state where the outside light is prevented from entering the photodetector; and an abnormality determiner configured to determine a deterioration state of the photodetector by using the output signal outputted from the photodetector in the dark state and a determination threshold.

### CROSS-REFERENCE TO RELATED APPLICATION

The present application is based on and claims the benefit of priority from earlier Japanese Patent Application No. 2019-040535 filed on Mar. 6, 2019, the description of which is incorporated herein by reference.

### BACKGROUND

### Technical Field

The present disclosure relates to an optical ranging device.

### Related Art

An optical ranging device is disclosed which applies light to a target and measures a distance to the target by using time of flight (TOF) of light elapsed before a reflected light is received.

### SUMMARY

An aspect of the present disclosure provides an optical ranging device including: a photodetector configured to output an output signal corresponding to an amount of received light; a scanning scanner configured to switch between a state where outside light is permitted to enter the photodetector and a dark state where the outside light is prevented from entering the photodetector; and an abnormality determiner configured to determine a deterioration state of the photodetector by using the output signal outputted from the photodetector in the dark state and a determination threshold.

### BRIEF DESCRIPTION OF THE DRAWINGS

In the accompanying drawings:

FIG. 1 is a diagram for explaining a vehicle and an optical ranging device mounted in the vehicle;

FIG. 2 is a diagram for explaining a schematic configuration of the optical ranging device;

FIG. 3 is a diagram for explaining a first dark state;

FIG. 4 is a diagram for explaining a second dark state;

FIG. 5 is a diagram for explaining an operation time of a photodetector and the number of pulses per unit of time in a dark state;

FIG. 6 is a diagram for explaining a relationship between a temperature and a determination threshold;

FIG. 7 is a diagram for explaining a configuration of the photodetector;

FIG. 8 is a flowchart for determining whether a pixel unit has an abnormality, which is to be performed by an abnormality determiner in the dark state;

FIG. 9 is a diagram for explaining an example of a result of the flowchart in FIG. 8 being performed;

FIG. 10 is a flowchart for determining whether the photodetector is to be stopped, which is to be performed by the abnormality determiner; and

FIG. 11 is a diagram for explaining an example of a case where pixel units determined to be abnormal are adjacent to each other.

### DETAILED DESCRIPTION OF THE PREFERRED EMBODIMENTS

Japanese Patent Application Publication No. 2016-176750 discloses an optical ranging device that applies light to a target and measures a distance to the target by using time of flight (TOF) of light elapsed before a reflected light is received. The optical ranging device includes, as a photodetector, a SPAD (Single Photon Avalanche Diode) that operates in a Geiger mode.

It is known that such a photodetector deteriorates with age due to internal defects of a semiconductor constituting a SPAD. With progression of the deterioration with age, a dark current, which flows irrespective of light reception, increases, which would cause a malfunction such as a failure to accurately measure a distance. It is possible to inspect and determine whether the photodetector has an abnormality under a calibrated test environment such as an inspection stage prior to the optical ranging device being mounted in a vehicle. However, once the optical ranging device is mounted in a vehicle, light such as ambient light enters the photodetector under, for example, an outdoor lighting environment. The entrance of ambient light results in generation of a current, which is difficult to distinguish from a dark current. This makes it difficult to determine whether the photodetector has an abnormality after the optical ranging device is mounted in a vehicle. Accordingly, a technique enabling easy determination of whether the photodetector has an abnormality even after the optical ranging device is mounted in a vehicle has been demanded. It should be noted that this problem is of concern not only to a case where a photodetector includes a SPAD but also to a case where a photodetector includes a CCD or CMOS sensor.

### Overall Configuration:

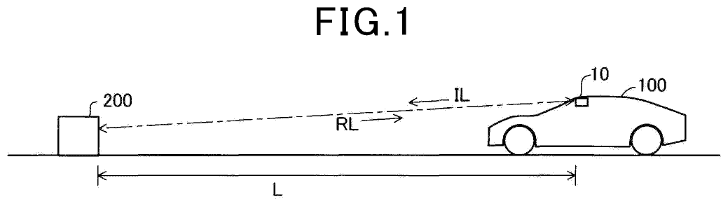

As illustrated in FIG. 1, an optical ranging device 10, which is mounted in a vehicle 100, measures a distance L to a target 200. Specifically, the optical ranging device 10 measures the distance L to the target 200 by using time TOF elapsed since an emitted beam IL is applied to the target 200 until the emitted light IL is reflected on the target 200 and a returned reflected light RL is received. When c denotes the speed of light, L=c·TOF/2.

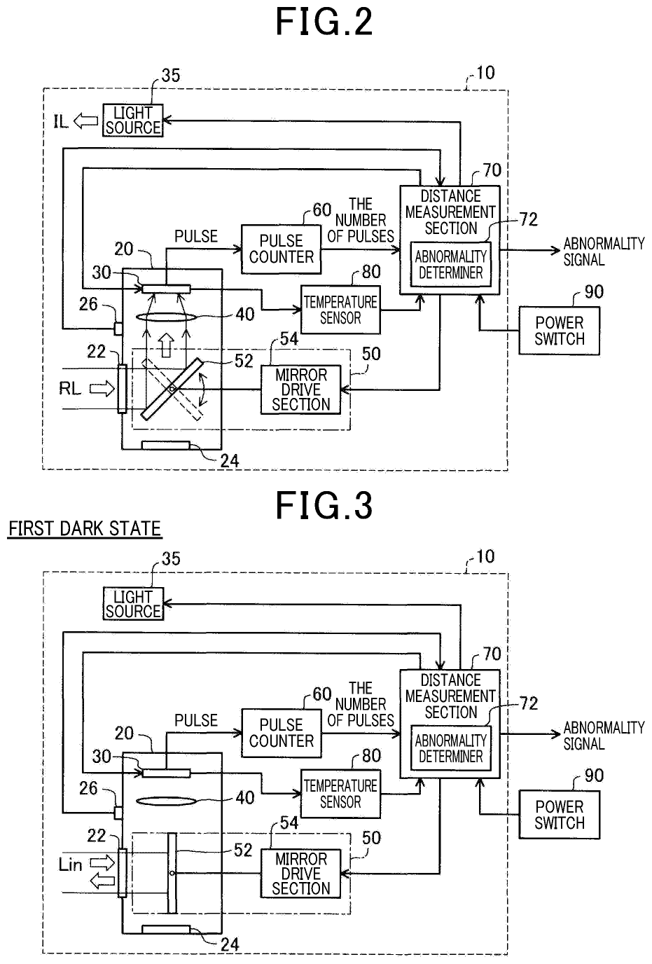

As illustrated in FIG. 2, the optical ranging device 10 includes a case 20, a photodetector 30, a light source 35, a condenser lens 40, a scanning scanner 50, a pulse counter 60, a distance measurement section 70, and a temperature sensor 80. The case 20, which is a case for housing the photodetector 30, includes a window 22, a non-reflective material 24, and a light sensor 26. The scanning scanner 50 includes a reflective mirror 52 and a mirror drive section 54. The distance measurement section 70 includes an abnormality determiner 72.

The photodetector 30, the condenser lens 40, the reflective mirror 52, and the non-reflective material 24 are housed inside the case 20. The case 20 is configured to have no opening except the window 22, so that light enters the inside only through the window 22. The reflective mirror 52 reflects the reflected light RL, which is the light entering through the window 22, in a direction toward the photodetector 30. The condenser lens 40, which is disposed between the photodetector 30 and the reflective mirror 52, concentrates the reflected light RL reflected on the light reflective mirror 52 on the photodetector 30. The photodetector 30, which includes, for example, a SPAD (Single Photon Avalanche Diode), generates pulses in accordance with the amount of the received reflected light RL. The pulse counter 60 counts the number of the pulses. The distance measurement section 70 calculates the distance to the target 200 by using the number of the pulses. Specifically, a time-based histogram of the number of pulses is created, time from emission of the emitted beam IL from the light source 35 to appearance of a peak in the histogram is considered as TOF, and the distance to the target 200 is calculated by using the TOF. It should be noted that although being not coaxial with the photodetector 30 in the present embodiment, the light source 35 may be coaxial therewith. In a case where the light source 35 is coaxial, it is housed inside the case 20.

### First Embodiment

A SPAD generates pulses and a dark current even when not being exposed to light. The pulse and dark current are generated due to deterioration of the SPAD with age attributed to an internal defect of a semiconductor constituting the SPAD. In other words, further deterioration of the SPAD causes the number of pulses and the dark current to increase. Accordingly, a dark state where the SPAD is not exposed to light is provided and the number of pulses or the dark current in the dark state is measured, which makes it possible to determine how much the SPAD, i.e., the photodetector 30, has been deteriorated.

The reflective mirror 52 is driven and rotated by the mirror drive section 54. Thus, the mirror drive section 54 can provide the dark state, in which no incident light Lin enters the photodetector 30, by rotating the reflective mirror 52 and causing the incident light Lin to be reflected toward the window 22 as illustrated in FIG. 3. This state is referred to as a “first dark state.” The incident light Lin includes sunlight and light entering from another light source directly or after reflected on another object. In a case where the light source 35 emits the emitted beam IL, the resulting reflected light RL is also included. Accordingly, it is preferable that the abnormality determiner 72 cause the light source 35 to emit no light because, if so, no reflected light RL is added to the incident light Lin. However, the abnormality determiner 72 may cause the light source 35 to emit light. This is because the reflected light RL, which is reflected on the reflective mirror 52, is unlikely to enter the photodetector 30.

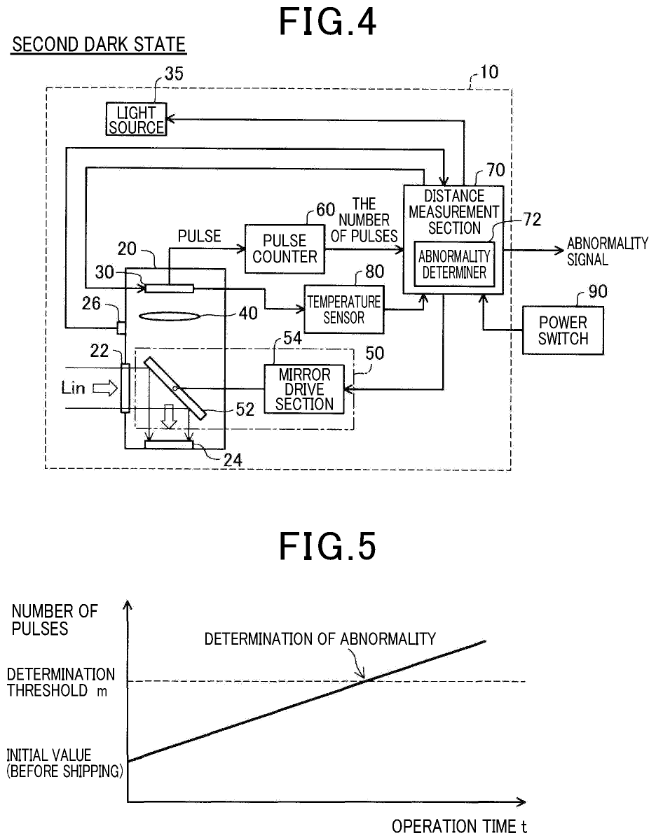

Further, the mirror drive section 54 can provide the dark state, in which no incident light Lin enters the photodetector 30, by rotating the reflective mirror 52 and causing the incident light Lin to be reflected toward the non-reflective material 24 as illustrated in FIG. 4. The non-reflective material 24 absorbs the incident light Lin reflected on the reflective mirror 52 instead of further reflecting it. This state is referred to as a “ second dark state.”

The abnormality determiner 72 illustrated in FIG. 2 to FIG. 4 determines whether the number of pulses generated per unit of time is equal to or more than a determination threshold m in the dark state such as the first dark state or the second dark state. The number of pulses per unit of time in the dark state increases with deterioration of the photodetector 30. The photodetector 30 is likely to deteriorate with an increase in the operation time. Therefore, the number of pulses per unit of time in the dark state increases with an increase in the operation time of the photodetector 30 as illustrated in FIG. 5. The time when the number of pulses per unit of time exceeds the determination threshold corresponds to the time of occurrence of an abnormality in the photodetector 30. It should be noted that the number of pulses does not actually linearly increase with respect to the operation time of the photodetector 30. A graph in FIG. 5 is not intended to graphically illustrate the actual operation time and number of pulses but provided as a graph illustrating the number of pulses linearly increasing with respect to the operation time for the purpose of simplicity.

The abnormality determiner 72 outputs an abnormality signal in response to determining that an abnormality has occurred in the photodetector 30 as a result of determination using the number of pulses and the determination threshold. The abnormality signal may be, for example, displayed on an instrument panel of the vehicle 100 or outputted as sound.

According to the first embodiment described above, the abnormality determiner 72 performs switching to the dark state, in which an outside light is prevented from entering the photodetector 30, by using the scanning scanner 50 and can easily determine a deterioration state of the photodetector 30 by using the number of pulses per unit of time in the dark state and the determination threshold.

In the above-described first embodiment, a SPAD is used as the photodetector 30 and the abnormality determiner 72 determines the abnormality or deterioration state of the photodetector 30 by using an output signal, i.e., the number of pulses, outputted from the photodetector 30 in the dark state; however, a CCD or MOS sensor, a phototransistor, or the like may be used as the photodetector 30. In this case, a dark current may be used in place of the number of pulses. It should be noted that these effects also apply to later-described other embodiments.

### Second Embodiment:

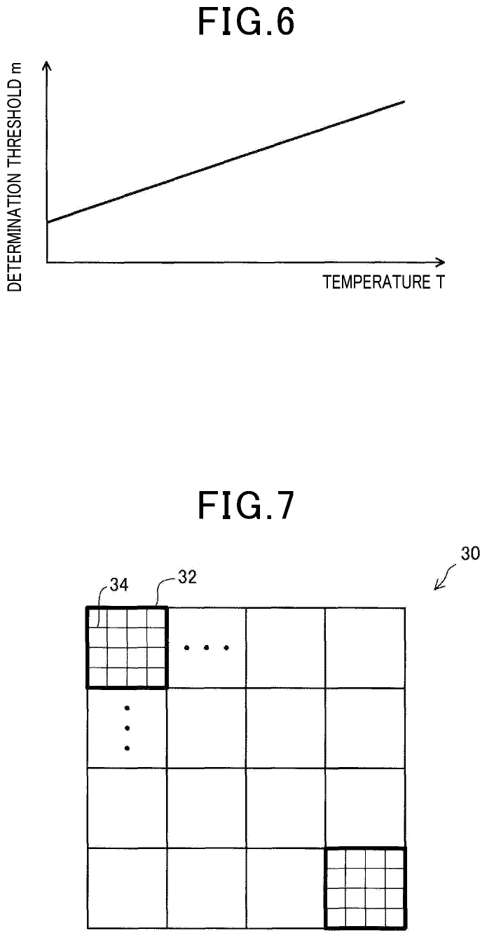

A second embodiment is an embodiment in which the determination threshold m cab be changed in accordance with a temperature of the photodetector 30. The temperature sensor 80 illustrated in FIG. 2 to FIG. 4 measures the temperature of the photodetector 30. The number of pulses and a dark current increase with a rise in the temperature of the photodetector 30. Thus, the photodetector 30, which is not deteriorated, would be erroneously determined to be deteriorated in a case where the temperature is high, since the number of pulses and a dark current increase. Accordingly, the abnormality determiner 72 may be able to change the determination threshold such that the determination threshold m increases with an increase in the temperature of the photodetector 30 as illustrated in FIG. 6. It should be noted that although a configuration where the temperature sensor 80 measures the temperature of the photodetector 30 is employed in the present embodiment, an outside air temperature sensor that measures an outside air temperature may be used in place of the temperature sensor 80. This is because the outside air temperature and the temperature of the photodetector 30 are expected to be substantially the same especially at the time of start of the vehicle 100. It should be noted that a configuration where no temperature sensor 80 is provided and the abnormality determiner 72 does not change the determination threshold m is also possible. Further, a measurement value may be corrected in accordance with the temperature instead of the determination threshold m being changed.

### Third Embodiment

A third embodiment is an embodiment where it is determined whether switching to the dark state is to be performed or the determination value m is changed in accordance with the intensity of light outside the case 20. The light sensor 26 illustrated in FIG. 2 to FIG. 4, which is provided on the same surface as the window 22, detects an intensity of light. The light to be detected by the light sensor 26 is substantially equal in intensity to light entering the inside of the case 20 from the outside. In a case where the intensity of light outside the case 20 is lower than the determination value, the abnormality determiner 72 performs switching to the dark state, so that it can be determined whether the photodetector 30 has an abnormality. This is because in a case where the intensity of light outside the case 20 is lower than the determination value, even if light outside the case 20 partially enters the photodetector 30 due to irregular reflection, the light is unlikely to cause a current to flow with pulses generated. It should be noted that the abnormality determiner 72 may be configured to change the determination threshold m in accordance with the intensity of light outside the case 20. Even in a case where the light outside the case 20 is not weak, the deterioration of the photodetector 30 can be easily determined.

### Fourth Embodiment

A fourth embodiment is an embodiment where it is determined whether the photodetector 30 has an abnormality at the time of at least one of the start or stop of the optical ranging device 10. A power switch 90 illustrated in FIG. 2 to FIG. 4 is a power switch for starting or stopping the vehicle 100. When the power switch 90 is turned on/off, the optical ranging device 10 is simultaneously tuned on/off. At the time of starting or stopping the vehicle 100, the vehicle 100 does not travel, so that it is not necessary to detect the object 200 by means of the optical ranging device 10. Accordingly, it is a good timing for the abnormality determiner 72 to determine the deterioration of the light detector 30 while the optical ranging device 10 is in the dark state. Further, a case where the power switch 90 of the vehicle 100 is to be turned on/off includes a case where the vehicle 100 is parked in a garage. In this case, the intensity of outside light can be lowered, which may facilitate determination of the deterioration of the photodetector 30. Further, the temperature of the photodetector 30 at the time when the power switch 90 of the vehicle 100 is turned on is substantially the same as an outside air temperature. This may make it possible to determine the deterioration of the photodetector 30 with the temperature of the photodetector 30 stable.

### Fifth Embodiment

A fifth embodiment is an embodiment where the photodetector 30 includes a plurality of pixel units 32 and light-receiving elements 34. In the fifth embodiment, the photodetector 30 includes the two-dimensionally arranged pixel units 32 and each of the pixel units 32 includes n (n is an integer of two or more) of the light-receiving elements 34 as illustrated in FIG. 7.

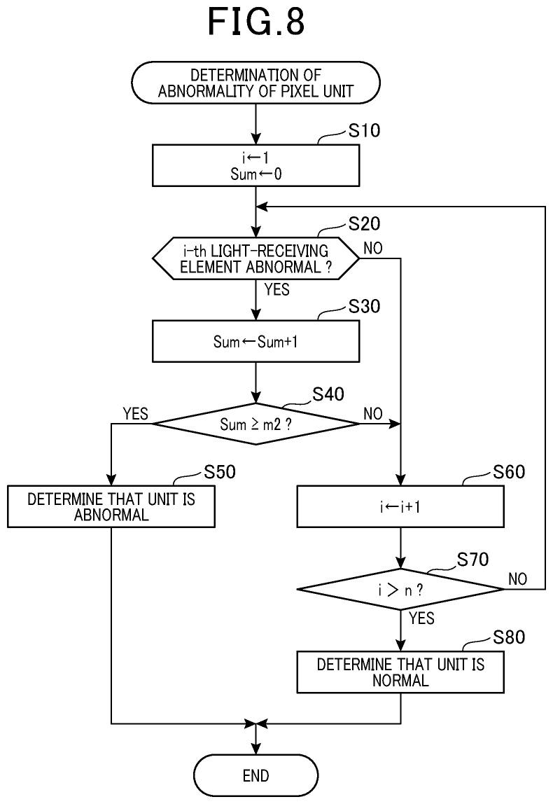

After performing switching to the dark state, in which outside light is prevented from entering the photodetector 30, by using the scanning scanner 50, the abnormality determiner 72 determines the abnormalities of the pixel units 32 according to, for example, a flowchart illustrated in FIG. 8. In Step S10, the abnormality determiner 72 sets a variable i to 1 and zero to a variable Sum. The variable i is a variable indicating numbers assigned to the light-receiving elements 34 and the variable Sum is a variable indicating the number of the light-receiving elements 34 determined to be abnormal.

In Step S20, the abnormality determiner 72 determines whether an abnormality has occurred in the i-th light-receiving element 34 by using the number of pulses at the i-th light-receiving element 34 per unit of time in the dark state and the determination threshold. The abnormality determiner 72 advances the process to Step S30 in response to the occurrence of an abnormality or advances the process to Step S60 in response to no occurrence of an abnormality.

In Step S30, the abnormality determiner 72 adds 1 to the variable Sum. In next Step S40, the abnormality determiner 72 determines whether a value of the variable Sum reaches a determination value m2 or more. The abnormality determiner 72 advances the process to Step S50 in response to the value of the variable Sum reaching the determination value m2 or more, determining that the pixel unit 32 is abnormal. In contrast, the process advances to Step S60 in response to the value of the variable Sum being less than the determination value m2.

In Step S60, the abnormality determiner 72 adds 1 to the variable i. In Step S70, the abnormality determiner 72 determines whether the variable i is larger than the number n of the light-receiving element 34 included in the pixel unit 32. The abnormality determiner 72 advances the process to Step S80 in response to the variable i being larger than n, determining that the pixel unit 32 is normal. In contrast, the abnormality determiner 72 advances the process to Step S20 in response to the variable i being equal to or less than n.

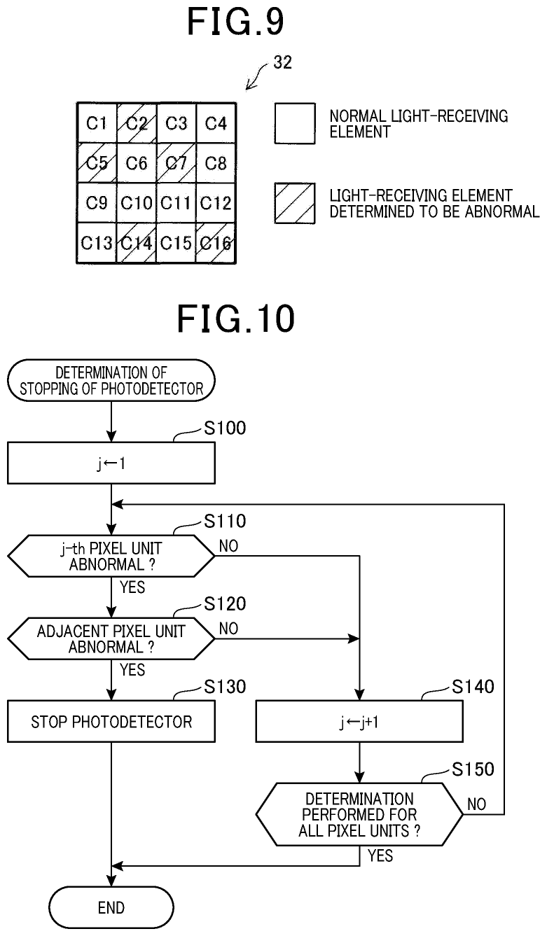

Assume that determination for each of the light-receiving elements 34 has been made as illustrated in FIG. 9. In this case, the abnormality determiner 72 determines, in response to the number of the light-receiving elements 34 determined to be abnormal being equal to or more than m (m is a natural number smaller than n), that the pixel unit 32 including the m light-receiving element 34 is abnormal. Here, it is preferable that m be set as a threshold sufficient to ensure a ranging performance of the optical ranging device 10.

According to the fifth embodiment described above, in a case where m (m is a natural number smaller than n) of the n light-receiving elements 34 is abnormal in any of the two-dimensionally arranged pixel units 32, the abnormality determiner 72 can determine that the pixel unit is abnormal.

### Sixth Embodiment

A sixth embodiment is an embodiment where in a case where a plurality of pixel units 32 are abnormal and the abnormal pixel units 32 are adjacent to each other, the photodetector 30 is stopped. Description will be made on a flowchart for determining whether the photodetector 30 is to be stopped illustrated in FIG. 10. In Step S100, the abnormality determiner 72 sets a variable i to 1. The variable j is a variable indicating numbers assigned to the pixel units 32.

In Step S110, the abnormality determiner 72 determines whether the j-th pixel unit has an abnormality according to the flowchart described with reference to FIG. 9. The abnormality determiner 72 advances the process to Step S120 in response to the j-th pixel unit having an abnormality or advances the process to Step S140 in response to the j-th pixel unit having no abnormality.

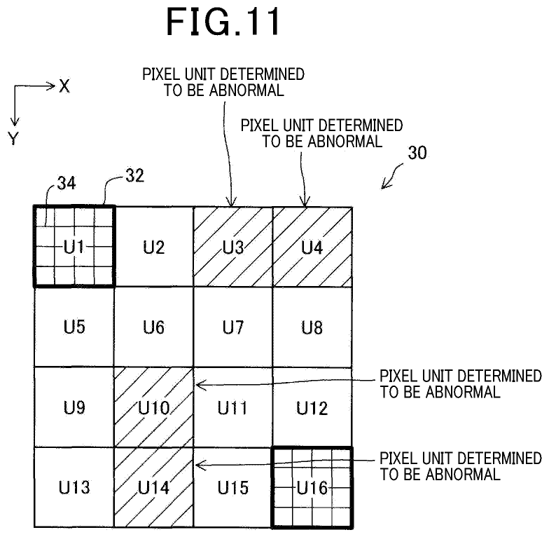

In Step S120, the abnormality determiner 72 determines whether the pixel unit 32 adjacent to the j-th pixel unit 32 has been determined to be abnormal. As illustrated in FIG. 11, the photodetector 30 includes the pixel units 32 of U1 to U16 and it is determined whether the pixel units 32 have abnormalities in an order from U1 to U16.

First, description will be given of a case where the pixel unit 32 determined to be abnormal is adjacent in an x-direction. In a case where the j-th pixel unit 32 is, for example, U3, U4 adjacent thereto is the pixel unit 32 that has not been determined to be abnormal or not even when the pixel unit 32 of U3 is determined to be abnormal. Thus, in the case where the j-th pixel unit 32 is U3, the result of Step S110 is Yes and the result of Step S120 is No, so that the abnormality determiner 72 advances the process to Step S140. In contrast, in a case where the j-th pixel unit 32 is, for example, U4, the pixel unit 32 of U4 is determined to be abnormal while U3 adjacent thereto has already been determined to be abnormal. Thus, in the case where the j-th pixel unit 32 is U4, the result of Step S110 is Yes and the result of Step S120 is also Yes, so that the abnormality determiner 72 advances the process to Step S130.

The same applies to a case where the pixel unit 32 determined to be abnormal is adjacent in a y-direction. In a case where the j-th pixel unit 32 is, for example, U10, U14 adjacent thereto is the pixel unit 32 that has not been determined to be abnormal or not even when the pixel unit 32 of U10 is determined to be abnormal. Thus, in the case where the j-th pixel unit 32 is U10, the result of Step S110 is Yes and the result of Step S120 is No, so that the abnormality determiner 72 advances the process to Step S140. In contrast, in a case where the j-th pixel unit 32 is, for example, U14, the pixel unit 32 of U14 is determined to be abnormal while U10 adjacent thereto has already been determined to be abnormal. Thus, in the case where the j-th pixel unit 32 is U14, the result of Step S110 is Yes and the result of Step S120 is also Yes, so that the abnormality determiner 72 advances the process to Step S130, stopping the photodetector 30 and reporting accordingly. This is because in a case where adjacent ones of the pixel units 32 have abnormalities, a small object would fail to be detected. However, the abnormality determiner 72 only has to report an abnormality and does not need to stop the photodetector 30. Further, in a case where abnormalities occur in a specific pattern, for example, adjacently in a 45-degree direction relative to the x- and y-directions instead of the x-direction or the y-direction, the abnormality determiner 72 may stop the photodetector 30.

In Step S140, the abnormality determiner 72 adds 1 to the variable j. In Step S150, the abnormality determiner 72 determines, for all of the pixel units 32, whether the determination whether the pixel unit is abnormal has been made. In a case where the determination whether the pixel unit is abnormal has not been made for some of the pixel units 32, the process advances to Step S110. In a case where the determination whether the pixel unit is abnormal has been made for all of the pixel units 32, the process is terminated.

According to the sixth embodiment described above, in response to an abnormality occurring in m of the n light-receiving elements, the pixel unit 32 is determined to be abnormal. This makes it possible to reduce determination of abnormalities of the pixel units 32 due to noise or the like. Further, in response to abnormalities of the pixel units 32 occurring in a specific pattern, the photodetector 30 is stopped. Thus, in a case where a small object is unlikely to be detected, it is possible to stop the photodetector 30 and issue an alert accordingly.

In the above-described embodiments, in response to any of the pixel units 32 having an abnormality, it is determined whether the adjacent pixel unit 32 also has an abnormality; however, it may be determined whether adjacent ones of the pixel units 32 have abnormalities after all the pixel units 32 are inspected to determine whether they have abnormalities and the determination is recorded in a storage device. However, according to the flowchart illustrated in FIG. 10, in response to any of the pixel units 32 having an abnormality, the photodetector 30 can be stopped before all the pixel units 32 are inspected, which makes it possible to reduce an inspection time.

In a case where inspection is to be performed after a while, the pixel unit determined to be abnormal during previous inspection and determination may be recorded in a storage device and, during the present inspection and determination, may be considered as abnormal and skipped. This is because the pixel unit 32 once determined to be abnormal is highly likely to be deteriorated.

In the above-described embodiments, the abnormality determiner 72 determines whether the photodetector 30 has an abnormality by using the number of pulses per unit of time in the dark state and the determination threshold; however, it may be determined whether the photodetector 30 has an abnormality by using a dark current of the photodetector 30 in the dark state.

The present disclosure is not limited to the above-described embodiments and may be implemented in a variety of configurations without departing from the spirit thereof. For example, in order to solve a part or all of the above-described problem or achieve a part or all of the above-described effects, the technical features of the embodiments may be appropriately replaced or combined. Further, unless being described to be essential herein, any of the technical features may be appropriately omitted.

According to an aspect of the present disclosure, an optical ranging device (10) is provided. The optical ranging device includes: a photodetector (30) configured to output an output signal corresponding to an amount of a received light; a scanning scanner (50) configured to switch between a state where outside light is permitted to enter the photodetector and a dark state where the outside light is prevented from entering the photodetector; and an abnormality determiner (72) configured to determine a deterioration state of the photodetector by using the output signal outputted from the photodetector in the dark state and a determination threshold.

According to this aspect, switching to the dark state is performed by the scanning scanner, so that the abnormality determiner can determine whether the photodetector has an abnormality by excluding the influence of light.

What is claimed is:

1. An optical ranging device comprising:
a photodetector configured to output an output signal corresponding to an amount of received light;
a scanning scanner configured to switch between a state where outside light is permitted to enter the photodetector and a dark state where the outside light is prevented from entering the photodetector; and
an abnormality determiner configured to determine a deterioration state of the photodetector by using the output signal outputted from the photodetector in the dark state and a determination threshold.

2. The optical ranging device according to claim 1, wherein the abnormality determiner is configured to change the determination threshold in accordance with a temperature.

3. The optical ranging device according to claim 1, wherein at a time of at least one of start and stop of the optical ranging device, the scanning scanner is configured to perform switching to the dark state and the abnormality determiner is configured to determine the deterioration state of the photodetector.

4. The optical ranging device according to claim 1, wherein the photodetector comprises a SPAD.

5. The optical ranging device according to claim 4, wherein the output signal includes a pulse, the optical ranging device further comprising a pulse counter configured to count the pulse.

6. The optical ranging device according to claim 1, wherein
the photodetector comprises two-dimensionally arranged pixel units, the pixel units each comprising n light-receiving elements, where n is an integer of two or more, and
the abnormality determiner is configured to determine, in a case where m, which is a natural number smaller than the n, of the n light-receiving elements in any of the pixel units is abnormal, that the pixel unit is abnormal.

7. The optical ranging device according to claim 6, wherein the abnormality determiner is configured to output an abnormality signal and stop the photodetector in a case where abnormal ones of the pixel units are adjacent to each other.

8. The optical ranging device according to claim 1, further comprising a light sensor configured to detect intensity of light, wherein
the scanning scanner is configured to perform switching to the dark state in a case where the intensity of the light detected by the light sensor is lower than a determination value.
